(19) United States
(12) Patent Application Publication
(10) Pub. No.: US 2016/0155970 A1
(43) Pub. Date: Jun. 2, 2016

(54) VERTICAL ORGANIC LIGHT-EMITTING TRANSISTOR AND ORGANIC LED ILLUMINATION APPARATUS HAVING THE SAME

(71) Applicant: SAMSUNG ELECTRONICS CO., LTD., Suwon-si, Gyeonggi-do (KR)

(72) Inventor: Dea-young CHUNG, Seoul (KR)

(73) Assignee: SAMSUNG ELECTRONICS CO., LTD., Suwon-si (KR)

(21) Appl. No.: 14/392,266

(22) PCT Filed: May 27, 2014
(86) PCT No.: PCT/KR2014/004691

§ 371 Date: Dec. 24, 2015

(30) Foreign Application Priority Data
Jun. 27, 2013 (KR) 10-2013-0074913

(51) Int. Cl. H01L 51/05; H01L 51/52; H01L 51/50

(52) U.S. Cl. CPC H01L 51/057; H01L 51/502; H01L 51/5296; H01L 51/5203; H01L 51/5072; H01L 51/5056; H01L 2251/5361

(57) ABSTRACT

Provided are vertical-type organic light-emitting transistors and organic LED illumination apparatuses. The organic LED illumination apparatus includes gate electrode lines that are disposed parallel to each other with predetermined gaps on a substrate; a gate insulating layer covering the gate electrode lines on the substrate; a plurality of first electrode lines that are disposed to overlap or perpendicularly cross the gate electrode lines on the gate insulating layer; a first charge transport layer covering the first electrode lines on the gate insulating layer; a plurality of active layers arranged in a matrix array facing the first electrode lines on the first charge transport layer; a second charge transport layer covering the active layers on the first charge transport layer; and a plurality of second electrode lines that are perpendicularly disposed with respect to the first electrode lines and traverse the active layers on the second transport layer.

### TECHNICAL FIELD

The present disclosure relates to vertical organic light-emitting transistors and organic light emitting diode (LED) illumination apparatuses containing the same.

### BACKGROUND ART

An organic light-emitting transistor is a transistor in which an organic light-emitting structure and a transistor are formed together. An organic light-emitting transistor emits light by applying a gate voltage when voltage is applied to two electrodes in the organic light-emitting structure. Organic light-emitting transistors are classified as either horizontal-type organic light-emitting transistors or vertical-type organic light emitting transistors, based on the disposition of the source electrode and the drain electrode.

### DISCLOSURE OF INVENTION

### Technical Problem

An illumination apparatus having an organic light-emitting transistor may be applied to an indoor illumination apparatus such as a wallpaper, a curtain, or a projection apparatus. A related art. OLED mainly emits monochromatic light (mainly white light), and conversion of the optical spectrum is not easy. Accordingly, the uses for OLEDs that emit monochromatic light are limited.

### Solution to Problem

One or more exemplary embodiments provide organic light-emitting transistors in which electrodes are vertically disposed and light is emitted upwards.

One or more exemplary embodiments also provide organic LED illumination apparatuses in which organic light-emitting transistors are disposed in an array to form sub-pixels, the organic light-emitting transistors are individually driven, and color light is emitted from a pixel that includes sub-pixels.

### Advantageous Effects of Invention

In the vertical-type organic light-emitting transistor according to the current embodiment, an organic light-emitting device and a transistor are formed as one body. Thus, an additional switching device is not required, and accordingly, the light emitting area is relatively large. Also, main constituent elements may be formed using a solution process, and thus the manufacturing method is simple. Also, since the source-drain voltage may be reduced as a result of the application of a gate voltage, power consumption may be reduced.

According to the organic LED illumination apparatus, the organic LED illumination apparatus may function as an interior when used as a wall illumination apparatus, and the color and intensity of light may be readily controlled. Also, a light-emitting area is large in each sub-pixel, and optical extraction efficiency is increased by controlling the gate voltage.

### BRIEF DESCRIPTION OF DRAWINGS

FIG. 1 is a schematic cross-sectional view of a vertical-type organic light-emitting transistor according to an exemplary embodiment;

FIG. 2 is a schematic view of a first electrode formed from a plurality of carbon nanotubes;

FIG. 3 is a view of a first electrode formed as a metal grid;

FIG. 4 is a schematic view of the structure of an organic LED illumination apparatus according to exemplary embodiments;

FIG. 5 is a cross-sectional view taken along line V-V′ of FIG. 4; and

FIG. 6 is a cross-sectional view taken along line VI-VI′ of FIG. 4.

### BEST MODE FOR CARRYING OUT THE INVENTION

According to an aspect of an exemplary embodiment, there is provided a vertical type organic light-emitting transistor including: a gate electrode, a first electrode, and a second electrode, which are sequentially formed on a substrate; an active layer between the first and second electrodes; a first charge transport layer between the first electrode and the active layer; and a second charge transport layer between the active layer and the second electrode, wherein the first electrode is formed as graphene or a porous electrode having a plurality of openings.

The first charge transport layer may be an electron transport layer, and the second charge layer may be a hole transport layer.

The porous electrode may include a plurality of carbon nanotubes, a plurality of metal nanowires, or a metal grid.

The active layer may include a plurality of quantum dots or an organic material.

The vertical-type organic light-emitting transistor may further include a gate insulating layer disposed between the gate electrode and the first electrode, wherein the gate insulating layer include an oxide semiconductor or an organic semiconductor.

The electron transport layer may contact the gate insulating layer through the porous electrode.

The second electrode may be a transparent electrode.

The gate electrode, the first electrode, and the second electrode may be formed so as to have substantially the same area.

According to an aspect of an exemplary embodiment, there is provided an organic LED illumination apparatus including: a plurality of gate electrode lines that are disposed parallel to each other with predetermined gaps on a substrate; a gate insulating layer covering the gate electrode lines on the substrate; a plurality of first electrode lines that are disposed to overlap or perpendicularly cross the gate electrode lines on the gate insulating layer; a first charge transport layer covering the first electrode lines on the gate insulating layer; a plurality of active layers arranged in a matrix array facing the first electrode lines on the first charge transport layer; a second charge transport layer covering the active layers on the first charge transport layer; and a plurality of second electrode lines that are perpendicularly disposed with respect to the first electrode lines and traverse the active layers on the second transport layer, wherein the first electrode lines are formed as a porous electrode having a plurality of openings or are graphene.

The organic LED illumination apparatus may further include a plurality of banks formed between the gate electrode lines on an upper surface of the substrate.

The banks may have a height that is substantially the same as that of the gate electrode lines.

The active layer may emit one of blue light, green light, and red light by combining charges through the first electrode lines and the second electrode lines.

The gate insulating layer may have a microcavity structure, and may be formed to a predetermined thickness according to a wavelength of light emitted from the active layer.

The electron transport layer may be formed to contact the gate insulating layer through the porous electrode.

The hole transport layer may contact the electron transport layer with the active layer therebetween.

### MODE FOR THE INVENTION

Reference will now be made in detail to embodiments, examples of which are illustrated in the accompanying drawings. In the drawings, the thicknesses of layers and regions may be exaggerated for clarity. It will be understood, however, that the exemplary embodiments may have many alternate forms and this disclosure should not be construed as being limited to only the exemplary embodiments set forth herein. It will also be understood that when an element or layer is referred to as being “on” or “above” another element or layer, the element or layer may be directly on the another element or layer or there may be intervening elements or layers between them. In the drawings, like reference numerals refer to like elements throughout, and duplicative descriptions thereof will be omitted for the sake of brevity.

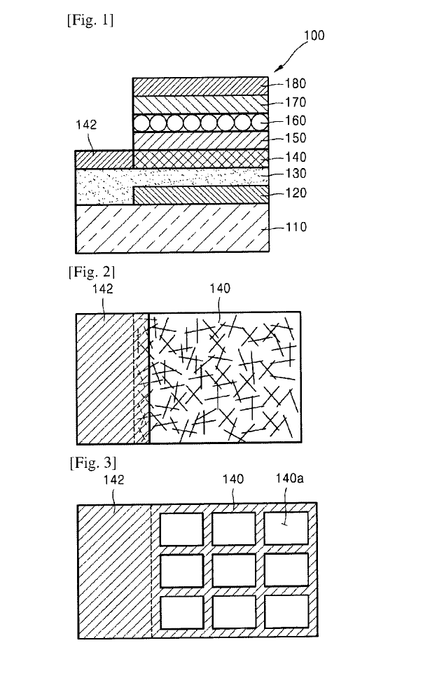

FIG. 1 is a schematic cross-sectional view of a vertical-type organic light-emitting transistor 100 according to an exemplary embodiment.

Referring to FIG. 1, the vertical-type organic light-emitting transistor 100 may include a gate electrode 120, a gate insulating layer 130, a first electrode 140, a first charge transport layer 150, an active layer 160, a second charge transport layer 170, and a second electrode 180, which are sequentially formed on a substrate 110. One of the first electrode 140 and the second electrode 180 may be a drain electrode, and the other one may be a source electrode. In the current embodiment, the first electrode 140 is a drain electrode, the first charge transport layer 150 is an electron transport layer, the second electrode 180 is a source electrode, and the second charge transport layer 170 is a hole transport layer. The vertical-type organic light-emitting transistor 100 that emits light upwards will now be described.

The gate electrode 120, the first electrode 140, and the second electrode 180 may have substantially the same shape or area, and may be formed by vertically stacking them on the substrate 110.

The substrate 110 may be formed of glass, silicon, quartz, or polymer. The polymer may be selected from the group consisting of polyethylenenaphthalate (PEN), polyethyleneterephthalate (PET), polycarbonate, polyvinylalcohol, polyacrylate, polyimide, polynorbornene, and polyethersulfone (PES), but the present embodiment is not limited thereto.

The gate electrode 120 may be a reflective electrode. The gate electrode 120 may increase optical extraction efficiency by reflecting light emitted from the active layer 160 upwards, away from the substrate 110. The gate electrode 120 may be formed of Al or Ag. When the gate electrode 120 is formed of a metal, it may be formed by dispersing a metal powder in a solution, and then coating the solution that includes the metal powder on the substrate 110. Afterwards, the metal powder becomes the gate electrode 120 via an annealing process. When the gate electrode 120 is formed of an oxide, the gate electrode 120 may be formed using a solution process after the oxide is dispersed in a solution.

The gate insulating layer 130 may be formed of a polymer, such as poly(methyl methacrylate) (PMMA) or poly(2?hydroxyethyl methacrylate) (PHEMA), or an oxide, such as ZnO or TiO2. When the gate insulating layer 130 is formed from a polymer, the gate insulating layer 130 may be formed so as to have a large area by using a solution process.

The gate insulating layer 130 may have a microcavity structure. The microcavity structure may increase an optical extraction efficiency of a specific wavelength emitted from the active layer 160. The thickness of the gate insulating layer 130 having the microcavity structure may be adjusted based on the wavelength of light to be emitted from the active layer 160.

The first electrode 140, that is, the drain electrode in the present embodiment, is a thin conductive layer and may be formed as a porous electrode having a plurality of openings or graphene.

The porous electrode may be formed by irregularly connecting a plurality of carbon nanotubes or a plurality of metal nanowires to each other. For example, after dispersing carbon nanotubes having a length in a range of from about a few nm to about a few tens of ?m in a solution, the solution that contains the carbon nanotubes may be coated on the gate insulating layer 130 using a solution process. Afterwards, the porous electrode formed from a plurality of carbon nanotubes may be formed on the gate insulating layer 130 via a drying process.

The metal nanowire may be formed from a general electrode material, such as Ag, Al, Au, or Mg.

FIG. 2 is a schematic view of the first electrode 140 formed from a plurality of carbon nanotubes.

Referring to FIGS. 1 and 2, after coating a solution that contains a plurality of carbon nanotubes on the gate insulating layer 130, a porous electrode is formed by drying the solution. The carbon nanotubes on the gate insulating layer 130 are tangled with each other, and an electrode pad 142 via which power from an external power source is supplied is formed on a side of the gate insulating layer 130. The carbon nanotubes are connected to each other so that a voltage applied from the electrode pad 142 is applied to each of the carbon nanotubes.

The structure of a drain electrode formed from a plurality of metal nanowires may be well-known from FIG. 2, and thus, the detailed description thereof will be omitted.

The porous electrode may be formed as a metal grid. FIG. 3 is a view of the first electrode 140 formed as a metal grid.

Referring to FIG. 3, the first electrode 140 as a drain electrode includes a grid having a lattice structure, and the electrode pad 142 is connected to a side of the grid 140.

The first electrode 140 includes a plurality of openings 140a through which an electric field from the gate electrode 120 passes.

The first electrode 140 may be formed of graphene. A potential energy of the first electrode 140 formed of graphene is increased by the application of voltage to the gate electrode 120, and accordingly, electrons may be readily moved from the first electrode 140 to the first charge transport layer 150.

The first charge transport layer 150 may include an n-type organic semiconductor or an n-type inorganic semiconductor. The n-type organic semiconductor may be a monomer or a polymer. For example, the n-type inorganic semiconductor may be an n-type oxide semiconductor, such as TiO2, ZnO, or ZrO2, or an n-type non-oxide semiconductor, such as n-GaN. The n-type organic semiconductor may include an organic material based on a monomer, such as Alq3, TAZ, TPBi, or BPhen, or an organic material based on a polymer, such as F8BT. The chemical names of Alq3, TAZ, BPhen, and F8BT are as follows:

Alq3: tris-(8-hydroxyquinilone)aluminum

TAZ: 3-(4-biphenyl)-4-phenyl-5-(4-tert-butylphenyl)-1,2,4-triazole

TPBi: 2,2,2-(1,3,5-benzinetriyl)-tris(1-phenyl-1-H-benzimidazole)

BPhen: 4,7-diphenyl-1,10-phenanthroline

F8BT: poly(9,9-dioctylfluorene-co-benzothiadiazole)

However, the materials listed above are merely exemplary materials for forming the first charge transport layer 150. Besides the materials listed above, the first charge transport layer 150 may be formed of various materials. The first charge transport layer 150 may be formed by a sol-gel method, a spray coating method, a spin coating method, a blade coating method, a printing method, or a deposition method, for example.

The first charge transport layer 150 may be formed of quantum dots having inorganic ligands on the surfaces thereof.

The active layer 160 may be a layer that includes a plurality of quantum dots. In this case, the quantum dots of the active layer 160 may be formed by using a colloidal solution. Accordingly, the quantum dots may be colloidal quantum dots. The quantum dots may be nano-sized structures formed of an inorganic semiconductor. For example, the quantum dots may include a group 11-VI semiconductor, such as CdSe, CdS, and CdTe, a group III-V semiconductor, such as InP, GaAs, and GaP, a group IV semiconductor, such as Si and Ge, and a group IV-VI semiconductor, such as PbSe, PbTe, and PbS.

Also, the quantum dots may have a core-shell structure. For example, the quantum dots may have a CdSe/ZnS structure or an InP/ZnS structure. As noted here, CdSe and InP are the cores, and ZnS is the shells.

The quantum dots may have core-shell structure having multiple shells. In this case, the quantum dots may have, for example, a CdSe/CdS/ZnS structure or an InP/ZnS/CdS/ZnS structure. As noted here. CdSe and InP are the cores and CdS and ZnS are the shells. However, the materials of the quantum dots described above are merely exemplary, and the quantum dots may be formed from various materials. Also, as necessary, an organic layer may be formed on a surface of the quantum dot.

The active layer 160 may be formed by coating a solution of quantum dots dispersed in an organic solvent using a solution process, and then vaporizing the organic solvent. The active layer 160 may be formed by coating the solution containing the organic solvent and quantum dots on an active layer region using an inkjet method, a slit coating method, a nozzle coating method, a spin coating method, or an imprinting method. The active layer 160 may be also formed on a predetermined region by further performing a patterning process and the related exposure.

The quantum dot may be a semiconductor nanoparticle. Quantum dots having a diameter in the range from about 1 nm to about 99 nm emit light when unstable electrons move from a conduction band to a valence bad. At this point, quantum dots having a small particle size emit light having a short wavelength, and quantum dots having a large diameter emit light having a long wavelength. Accordingly, when the size of the quantum dots is controlled, visible light having a desired wavelength may be obtained, and also, light of various colors may be simultaneously obtained by using various sizes of quantum dots. An organic ligand may be formed on surfaces of the quantum dots.

The active layer 160 may be formed from an organic material instead of quantum dots. The organic material may be a monomer or polymer.

The organic material may be poly(9,9-dioctylfluorene-co-benzothiadiazole) (F8BT), poly(9,9-dioctylfluorene-co-bithiophene) (F8T2), lumation green, poly(9,9-dioctylfluorene) (PFO), MEH-PPV: poly[2-methoxy-5-(2′-ethylhexyloxy)-1,4-phenylenevinylene], or tetraphenylbenzidine (TPD).

The second charge transport layer 170 may include a p-type organic semiconductor or a p-type inorganic semiconductor. The p-type inorganic semiconductor may be an oxide or a non-oxide, and the p-type organic semiconductor may be a monomer or a polymer. The p-type inorganic semiconductor may be a p-type oxide semiconductor, such as MoO3, NiO, V2O5, or Rh2O3. The p-type organic semiconductor may include an organic material based on a monomer, such as NPD or TPD, or an organic material based on a polymer, such as TFB, PFB, or F8T2. The chemical names of NPD, TPD, TFB, PFB, and F8T2 are as follows:

NPD: N,N′-diphenyl-N,N′-bis(1-naphthyl)-1,1′biphenyl-4,4diamine

TPD: N,N′-bis(3-methylphenyl)-N,N′-diphenylbenzidine

TFB: poly(9,9-dioctylfluorene-co-N-(4-butylphenyl)diphenylamine)

PFB: poly(9,9-dioctylfluorene-co-bis-N,N-phenyl-1,4-phenylenediamine)

F8T2: poly(9,9-dioctylfluorene-co-bithiophene)

However, the materials listed above are merely exemplary materials for forming the second charge transport layer 170. Besides the materials listed above, the second charge transport layer 170 may be formed from various materials. The second charge transport layer 170 may be formed by using a method selected from the group consisting of a sol-gel method, a spray coating method, a spin coating method, a blade coating method, a printing method, and a deposition method.

The second charge transport layer 170 may be a layer of quantum dots having inorganic ligands on surfaces thereof.

The second electrode 180 may be a transparent electrode formed from a material including indium tin oxide (ITO), indium zinc oxide (IZO), antimony zinc oxide (AZO), indium tin zinc oxide (ITZO), and SnO2.

The vertical-type organic light-emitting transistor 100 described above may be referred to as an inverted quantum dot LED, and light is emitted towards a front side, away from the substrate.

Hereinafter, an operation of the vertical-type organic light-emitting transistor 100 will be described.

When a voltage is applied to the second electrode 180 and the first electrode 140, electrons are injected into the active layer 160 from the first charge transport layer 150 and holes are injected into the active layer 160 from the second charge transport layer 170. Light is emitted when the electrons and holes injected into the active layer 160 combine. The wavelength of light emitted from the active layer 160 may vary based on the hand gap energy of the active layer 160.

However, if the drain voltage is less than a predetermined voltage, that is, a threshold voltage, light is not emitted from the active layer 160.

When a gate voltage is applied to the gate electrode 120, polarization occurs in the gate insulating layer 130 and electron density in the first charge transport layer 150 is changed, and thus, the rate of electron injection into the active layer 160 may be changed. When the gate voltage has a negative value, a hole injection rate is increased, and when the gate voltage has a positive value, an electron injection rate may be increased. Also, a field generated by the gate voltage enhances the light emission of the active layer 160 since the field has an effect on the first charge transport layer 150 through the openings of the first electrode 140.

When the first electrode 140 is formed of graphene, the work function of the graphene is changed by the gate voltage. For example, when a positive gate voltage is applied to the first electrode 140, the Fermi level of the graphene moves in a positive direction, and accordingly, the injection of electrons from the first electrode 140 to the first charge transport layer 150 is easy, and thus, light emission is easy.

The intensity of light emitted from the active layer 160 may be increased by increasing the gate voltage.

In the vertical-type organic light-emitting transistor 100 according to the current embodiment, an organic light-emitting device and a transistor are formed as one body. Thus, an additional switching device is not required, and accordingly, the light-emitting area is relatively large. Also, main constituent elements may be formed using a solution process, and thus the manufacturing method is simple. Also, since the source-drain voltage may be reduced as a result of the application of a gate voltage, power consumption may be reduced.

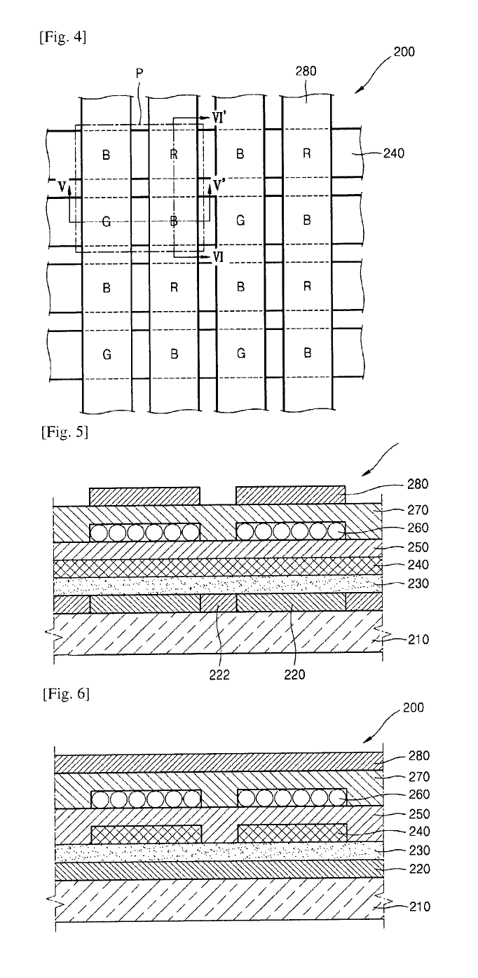

FIG. 4 is a schematic view of a structure of an organic LED illumination apparatus 200 according to an exemplary embodiment. FIG. 5 is a cross-sectional view taken along line V-V′ of FIG. 4. FIG. 6 is a cross-sectional view taken along line VI-VI′ of FIG. 4.

Referring to FIG. 4, the organic LED illumination apparatus 200 includes a plurality of pixels P disposed in an array. Each pixel P includes sub-pixels R, G, and B that emit, for example, red, green, and blue light, respectively. In FIG. 4, it is depicted that two blue sub-pixels B, one green sub-pixel G, and one red sub-pixel R are included in a single pixel P, but the present embodiment is not limited thereto. For example, a single pixel P may include one blue sub-pixel B, one green sub-pixel G, and one red sub-pixel R. Also, the sub-pixel may emit a different color of light, rather than the pictured blue light, green light, and red light. Each of the sub-pixels may have the structure of the vertical-type organic light-emitting transistor 100 of FIG. 1. In order to emit light from each sub-pixel, the energy hand gap of the active layer 260 may be different.

Source electrode lines 280 perpendicularly crossing drain electrode lines 240 may be formed above the drain electrode lines 240. Sub-pixel regions are where the drain electrode lines 240 meet the source electrode lines 280.

Referring to FIGS. 4 through 6, a plurality of gate electrode lines 220 are disposed parallel to each other with predetermined gaps between them. The substrate 210 may be formed of glass, silicon, quartz, or polymer.

In FIG. 5, the gate electrode lines 220 are formed to correspond to the source electrode lines 280. However, the current embodiment is not limited thereto, and, for example, the gate electrode lines 220 may be formed to correspond to the drain electrode lines 240.

The gate electrode lines 220 may be formed from Al or Ag. When the gate electrode lines 220 are formed of a metal, they may be formed by coating on the substrate 210 a metal powder dispersed in a solution. Afterwards, via an annealing process, the metal powder becomes the gate electrode lines 220. Also, when the gate electrode lines 220 are formed from an oxide, the gate electrode lines 220 may be formed using a solution process after dispersing the oxide in a solution. The gate electrode lines 220 may be reflective electrodes that increase optical extraction efficiency by reflecting light emitted from the active layer 260 upwards, away from the substrate.

A plurality of banks 222 that define the gate electrode lines 220 are formed on the substrate 210. The banks 222 may be formed in a strip shape in the same direction as the gate electrode lines 220. The banks 222 may be formed so as to have substantially the same height as the gate electrode lines 220. That is, the banks 222 may provide a flat upper surface together with the gate electrode lines 220.

The banks 222 may be formed from the same material as the substrate 210. The banks 222 may be formed by etching a surface of the substrate 210 or, after forming a layer on the substrate 210, the banks 222 may be formed by patterning the layer.

A gate insulating layer 230 is formed on the gate electrode lines 220 and the banks 222. The gate insulating layer 230 may be formed from a polymer material, such as PMMA or PHEMA, or an oxide, such as ZnO2 or TiO2. When the gate insulating layer 230 is formed from a polymer material, a gate insulating layer 230 having a large area may be formed by using a solution process.

The gate insulating layer 230 may have a microcavity structure. The microcavity structure may increase the optical extraction efficiency of light having a specific wavelength emitted from the active layer 260. The thickness of the gate insulating layer 230 having a microcavity structure may vary based on the emitted light.

The drain electrode lines 240 are disposed parallel to each other on the gate insulating layer 230. The drain electrode lines 240 are thin conductive layers and may be formed as porous electrodes or graphene having a plurality of openings. Each of the drain electrode lines 240 are formed above sub-pixels of a corresponding row of the array.

The porous electrode may be formed by irregularly connecting a plurality of carbon nanotubes or a plurality of metal nanowires to each other. For example, after dispersing carbon nanotubes having a length in a range of from about a few nm to about a few tens of ?m in a solution, the solution that contains the carbon nanotubes may be coated on the gate insulating layer 230 by using a solution process. Afterwards, the porous electrode formed from a plurality of carbon nanotubes may be formed on the gate insulating layer 130 via a drying process.

The metal nanowire may be formed from a general electrode material, such as Ag, Al, Au, or Mg.

The drain electrode lines 240 may be formed as a metal grid. The metal grid may be formed from a general electrode material, such as Ag, Al, Au, or Mg.

An electron transport layer 250 covering the drain electrode lines 240 is formed above the gate insulating layer 230. The electron transport layer 250 may include an n-type organic semiconductor or an n-type inorganic semiconductor. The n-type organic semiconductor may be a monomer or a polymer. The electron transport layer 250 may be formed by using methods such as a sol-gel method, a spray coating method, a spin coating method, a blade coating method, a printing method, and a deposition method.

The electron transport layer 250 may be formed from quantum dots having inorganic ligands on the surfaces thereof.

The electron transport layer 250 may be formed so as to contact the gate insulating layer 230 through the openings of the drain electrode lines 240.

An active layer 260 is formed in each of the sub-pixel regions on the electron transport layer 250. The active layer 260 may be formed from quantum dots or an organic material, and a detailed description thereof is not included herein. The active layer 260 generates, e.g., blue light, green light, or red light based on the size of the quantum dots. When the active layer 260 is formed from an organic material, the active layer 260 emits blue light, green light, or red light based on the organic material used. For example, if the active layer 260 is formed from PFO (poly(9,9-dioctylfluorene)) or TPD (tetraphenylbenzidine), the active layer 260 emits blue light; when the active layer 260 is formed from F8BT (poly(9,9-dioctylfluorene-co-benzothiadiazole)), F8T2 (poly(9,9-dioctylfluorene-co-bithiophene)), or Lumation green, the active layer 260 emits green light; and when the active layer 260 is formed from MEH-PPV (poly[2-methoxy-5-(2′-ethylhexyloxy)-1,4-phenylenevinylene], the active layer 260 emits red light.

A hole transport layer 270 covering the active layers 260 is formed on the electron transport layer 250. The hole transport layer 270 may include a p-type organic semiconductor or a p-type inorganic semiconductor. The hole transport layer 270 may be formed of quantum dots having an inorganic ligand on the surfaces thereof. The hole transport layer 270 may contact the electron transport layer 250, having the active layer 260 therebetween.

The source electrode lines 280 perpendicularly crossing the drain electrode lines 240 are formed on the hole transport layer 270. The source electrode lines 280 are formed to cross sub-pixels of a corresponding row. In the current embodiment, the source electrode lines 280 are formed so as to overlap the gate electrode lines 220. The source electrode lines 280 may be transparent electrodes formed of a material selected from the group consisting of ITO, IZO, AZO, ITZO, and SnO2.

When voltage is applied to the source electrode line 280 and the drain electrode line 240, a corresponding sub-pixel is addressed, and when voltage is applied to the gate electrode line 220 that passes through the addressed sub-pixel, corresponding light is emitted from the sub-pixel. When the voltage applied to two source electrode lines 280 and to two drain electrode lines 240 passing through a single pixel P is controlled, then the color of light emitted from the pixel P may be controlled. Also, the intensity of light emitted from the pixel P may be readily controlled by manipulating the intensity of the gate voltage.

According to the organic LED illumination apparatus 200 described above, the organic LED illumination apparatus 200 may function as an interior when used as a wall illumination apparatus, and the color and intensity of light may be readily controlled. Also, a light-emitting area is large in each sub-pixel, and optical extraction efficiency is increased by controlling the gate voltage.

It should be understood that the exemplary embodiments described herein should be considered to be descriptive only and not limiting. Descriptions of features or aspects within each embodiment should typically be considered as being available for other similar features or aspects in other embodiments.

### INDUSTRIAL APPLICABILITY

This invention may be applied to a vertical organic light-emitting transistor and an organic LED illumination apparatus having the vertical organic light-emitting transistor.

1. A vertical-type organic light-emitting transistor comprising:
a substrate;
a gate electrode disposed on the substrate;
a first electrode disposed on the gate electrode;
a first charge transport layer disposed on the first electrode;
an active layer disposed on the first charge transport layer;
a second charge transport disposed on the active layer;
a second electrode disposed on the second charge transport layer,
wherein the first electrode is graphene or a porous electrode having a plurality of openings.

2. The vertical-type organic light-emitting transistor of claim 1, wherein the first charge transport layer is an electron transport layer, and the second charge layer is a hole transport layer.

3. The vertical-type organic light-emitting transistor of claim 2, wherein the porous electrode comprises a plurality of carbon nanotubes, a plurality of metal nanowires, or a metal grid.

4. The vertical-type organic light-emitting transistor of claim 2, wherein the active layer comprises a plurality of quantum dots or an organic material.

5. The vertical-type organic light-emitting transistor of claim 2, further comprising a gate insulating layer disposed between the gate electrode and the first electrode, wherein the gate insulating layer comprises an oxide semiconductor or an organic semiconductor.

6. The vertical-type organic light-emitting transistor of claim 5, wherein the electron transport layer contacts the gate insulating layer through the porous electrode.

7. The vertical-type organic light-emitting transistor of claim 2, wherein the second electrode is a transparent electrode.

8. The vertical-type organic light-emitting transistor of claim 2, wherein the gate electrode, the first electrode, and the second electrode have substantially the same area.

9. An organic light emitting diode (LED) illumination apparatus comprising:
a substrate;
a plurality of gate electrode lines that are disposed on the substrate in parallel to each other and space apart by predetermined gaps;
a gate insulating layer that covers the plurality of gate electrode lines;
a plurality of first electrode lines that are disposed on the gate insulating layer and overlap or perpendicularly cross the plurality of gate electrode lines;
a first charge transport layer that covers the plurality of first electrode lines;
a plurality of active layers that are disposed on the first charge transport layer and arranged in a matrix array facing the plurality of first electrode lines;
a second charge transport layer that is disposed on the first charge transport layer and covers the plurality of active layers; and
a plurality of second electrode lines that are disposed on the second transport layer and perpendicularly cross the plurality of first electrode lines and traverse the plurality of active layers,
wherein the plurality of first electrode lines are graphene or a porous electrode having a plurality of openings.

10. The organic LED illumination apparatus of claim 9, further comprising a plurality of banks disposed on the substrate between the plurality of gate electrode lines.

11. The organic LED illumination apparatus of claim 10, wherein the banks have a height that is substantially the same as a height of the plurality of gate electrode lines.

12. The organic LED illumination apparatus of claim 9, wherein the first charge transport layer is an electron transport layer, and the second charge transport layer is a hole transport layer.

13. The organic LED illumination apparatus of claim 9, wherein the electrode is a porous electrode comprising plurality of carbon nanotubes, a plurality of metal nanowires, or a metal grid.

14. The organic LED illumination apparatus of claim 10, wherein each of the plurality of active layers emits one of blue light, green light, and red light by combining charges from one of the plurality of first electrode lines and one of the plurality of second electrode lines.

15. The organic LED illumination apparatus of claim 14, wherein the plurality of active layers comprise a plurality of quantum dots or an organic material.

16. The organic LED illumination apparatus of claim 12, wherein the electron transport layer contacts the gate insulating layer through the porous electrode.

17. The organic LED illumination apparatus of claim 9, wherein the plurality of source electrode lines are transparent electrodes.

18. The organic LED illumination apparatus of claim 9, wherein the hole transport layer contacts the electron transport layer with the plurality of active layers therebetween.

19. The vertical-type organic light-emitting transistor of claim 2, wherein the vertical-type organic light-emitting transistor does not comprise an additional switching device.

20. The organic LED illumination apparatus of claim 9, wherein the organic LED illumination apparatus does not comprise an additional switching device.
